(19) United States
(12) Patent Application Publication
(10) Pub. No.: US 2024/0280906 A1
(43) Pub. Date: Aug. 22, 2024

(54) SUBSTRATE PROCESSING BAFFLE, SUBSTRATE PROCESSING APPARATUS INCLUDING THE SAME, AND SUBSTRATE PROCESSING METHOD USING THE SAME

(71) Applicant: Samsung Electronics Co., Ltd., Suwon-si (KR)

(72) Inventors: SANGJINE PARK, Suwon-si (KR); Ji Hwan PARK, Suwon-si (KR); KUNTACK LEE, Suwon-si (KR)

(21) Appl. No.: 18/244,974

(22) Filed: Sep. 12, 2023

(30) Foreign Application Priority Data
Feb. 17, 2023 (KR) 10-2023-0021596
Apr. 13, 2023 (KR) 10-2023-0048836

(51) Int. Cl. G03F 7/16; H01L 21/67

(52) U.S. Cl. CPC G03F 7/168; H01L 21/67034

(57) ABSTRACT

Disclosed are substrate processing baffle, substrate processing apparatuses, and substrate processing methods. The substrate processing baffle comprises a plate body having a central axis extending in a first direction, an upper body on the plate body, and partition members extending in a second direction intersecting the first direction. The plate body includes a fine passage that connects a top surface of the plate body to a bottom surface of the plate body, and a coupling hole downwardly recessed from the top surface of the plate body. The partition members are spaced apart from each other in a third direction that intersects each of the first direction and the second direction. The partition members are lower than the coupling hole.

### CROSS-REFERENCE TO RELATED APPLICATIONS

This U.S. nonprovisional application claims priority under 35 U.S.C. § 119 to Korean Patent Applications No. 10-2023-0021596 filed on Feb. 17, 2023, and No. 10-2023-0048836 filed on Apr. 13, 2023, in the Korean Intellectual Property Office, the disclosures of both of which are hereby incorporated by reference in their entireties.

### BACKGROUND

The present inventive concepts relate to a substrate processing baffle, a substrate processing apparatus, and a substrate processing method, and more particularly, to a substrate processing baffle capable of uniformly spraying a fluid, a substrate processing apparatus including the same, and a substrate processing method using the same.

A semiconductor device may be fabricated through various processes. For example, the semiconductor device may be manufactured through a photolithography process, an etching process, a deposition process, and a plating process. During a photolithography process for fabricating a semiconductor device, a wet process may be performed to coat liquid, such as a developer, on a wafer. In addition, a dry process may be executed to remove the liquid coated on the wafer. Various methods may be used to coat the liquid on the wafer or to remove the liquid from the wafer.

### SUMMARY

Some embodiments of the present inventive concepts provide a substrate processing baffle capable of uniformly spraying a supercritical fluid, a substrate processing apparatus including the same, and a substrate processing method using the same.

Some embodiments of the present inventive concepts provide a substrate processing baffle capable of controlling a flow of supercritical fluid at a position below a coupling hole, a substrate processing apparatus including the same, and a substrate processing method using the same.

Some embodiments of the present inventive concepts provide a substrate processing baffle capable of easily cleaning a substrate, a substrate processing apparatus including the same, and a substrate processing method using the same.

The object of the present inventive concepts is not limited to those mentioned above, and other objects which have not been mentioned above will be clearly understood to those skilled in the art from the following description.

According to some embodiments of the present inventive concepts, a substrate processing baffle may comprise: a plate body that has a central axis extending in a first direction; an upper body on the plate body; and a plurality of partition members that extend in a second direction intersecting the first direction, the second direction being a horizontal direction. The plate body may include: a fine passage that connects a top surface of the plate body to a bottom surface of the plate body; and a coupling hole downwardly recessed from the top surface of the plate body. The plurality of partition members may be spaced apart from each other in a third direction that intersects each of the first direction and the second direction. The plurality of partition members may be lower than the coupling hole.

According to some embodiments of the present inventive concepts, a substrate processing apparatus may comprise: a dry chamber housing that provides a drying space; and a substrate processing baffle in the dry chamber housing. The substrate processing baffle may include: a plate body; and a plurality of partition members combined with the plate body, the plurality of partition members extending in a horizontal direction. The plate body may include: a fine passage exposed on a bottom surface of the plate body; and a coupling hole exposed on a top surface of the plate body. The plurality of partition members may be below the coupling hole and spaced apart from each other.

According to some embodiments of the present inventive concepts, a substrate processing baffle may comprise: a plate body; and a plurality of partition members that extend in a horizontal direction. The plate body may include: a fine passage member that has a triply periodic minimal surface (TPMS) structure defining a fine passage; and a plurality of coupling members that provide a coupling hole. The fine passage member may have a circular shape when viewed in plan. The plurality of coupling members may be spaced apart from each other in a circumferential direction in the fine passage member. The fine passage may connect a top surface of the fine passage member to a bottom surface of the fine passage member. The coupling hole may be exposed on a top surface of the coupling member. The plurality of partition members may be below the coupling hole. The plurality of partition members may be spaced apart from each other to form a channel between the plurality of partition members.

According to some embodiments of the present inventive concepts, a substrate processing method may comprise: performing a wet process on a substrate; and performing a dry process on the substrate that has experienced the wet process. The step of performing the dry process on the substrate may include: placing the substrate into a dry chamber; and supplying a supercritical fluid into the dry chamber. The step of supplying the supercritical fluid into the dry chamber may include allowing the supercritical fluid supplied from a supercritical fluid supply to pass through a substrate processing baffle of the dry chamber. The substrate processing baffle may include: a plate body; and a plurality of partition members combined with the plate body. The plurality of partition members may extend in a horizontal direction. The plate body may include: a fine passage exposed on a bottom surface of the plate body; and a coupling hole exposed on a top surface of the plate body. The plurality of partition members may be below the coupling hole and spaced apart from each other.

Details of other example embodiments are included in the description and drawings.

### BRIEF DESCRIPTION OF DRAWINGS

FIG. 1 illustrates a simplified schematic diagram showing a substrate processing apparatus according to some example embodiments of the present inventive concepts.

FIG. 2 illustrates a cross-sectional view showing a cleaning chamber according to some example embodiments of the present inventive concepts.

FIG. 3 illustrates a cross-sectional view showing a dry chamber according to some example embodiments of the present inventive concepts.

FIG. 4 illustrates an enlarged cross-sectional view partially showing a dry chamber according to some example embodiments of the present inventive concepts.

FIG. 5 illustrates an enlarged cross-sectional view showing section X of FIG. 4.

FIG. 6 illustrates a cross-sectional view showing a fixing member according to some example embodiments of the present inventive concepts.

FIG. 7 illustrates a perspective view showing a substrate processing baffle and a coupling member according to some example embodiments of the present inventive concepts.

FIG. 8 illustrates a cut-away perspective view showing a substrate processing baffle and a coupling member according to some example embodiments of the present inventive concepts.

FIG. 9 illustrates an enlarged perspective view partially showing a substrate processing baffle according to some example embodiments of the present inventive concepts.

FIG. 10 illustrates a plan view showing a substrate processing baffle according to some example embodiments of the present inventive concepts.

FIG. 11 illustrates a bottom view showing a substrate processing baffle according to some example embodiments of the present inventive concepts.

FIG. 12 illustrates an enlarged bottom view showing section Y of FIG. 11.

FIG. 13 illustrates a simplified schematic diagram showing a supercritical fluid supply according to some example embodiments of the present inventive concepts.

FIG. 14 illustrates a flow chart showing a substrate processing method according to some example embodiments of the present inventive concepts.

FIGS. 15 and 16 illustrate diagrams showing an example substrate processing method according to the flow chart of FIG. 14.

FIG. 17 illustrates a bottom view showing a substrate processing baffle according to some example embodiments of the present inventive concepts.

FIG. 18 illustrates a bottom view showing a substrate processing baffle according to some example embodiments of the present inventive concepts.

FIG. 19 illustrates a bottom view showing a substrate processing baffle according to some example embodiments of the present inventive concept.

### DETAILED DESCRIPTION OF EMBODIMENTS

The following will now describe some example embodiments of the present inventive concepts with reference to the accompanying drawings. Like reference characters refer to like components throughout the description.

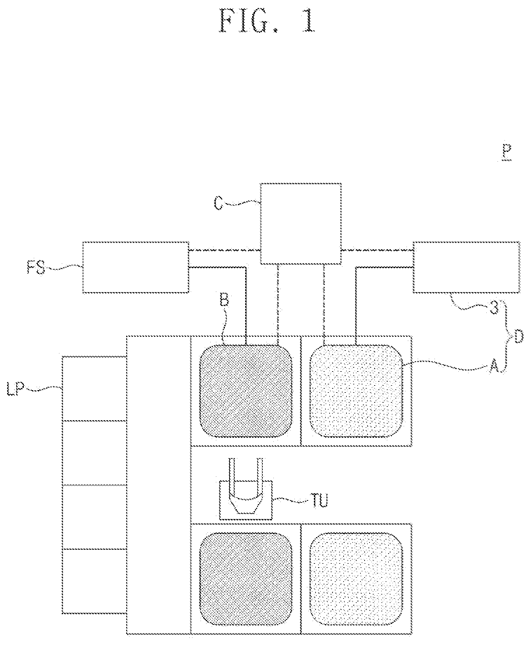

FIG. 1 illustrates a simplified schematic diagram showing a substrate processing apparatus according to some example embodiments of the present inventive concepts.

Referring to FIG. 1, a substrate processing system P may be provided. The substrate processing system P may be a device to process a substrate in a semiconductor fabrication process. For example, the substrate processing system P may be configured to execute a wet process and a dry process on a substrate. For example, the substrate processing apparatus P may provide a substrate with fluid to wet the substrate or may remove fluid from a substrate to dry and clean the substrate. The substrate processing apparatus P may spray a developer on a substrate that has experienced an extreme ultraviolet (EUV) exposure process. In addition, the substrate processing system P may dry a developer on a substrate. In this description, the term “substrate” may indicate a semiconductor wafer. The wafer may include a silicon (Si) wafer, but the present inventive concepts are not limited thereto. The substrate processing system P may include a loading port LP, a wet chamber B, a wetting solution supply FS, a transfer unit TU, a substrate processing apparatus D, and a controller C.

The loading port LP may be a port on which a substrate is loaded. For example, the loading port LP may load thereon a substrate that has experienced various semiconductor fabrication processes. The loading port LP may be provided in plural. A plurality of substrates may be correspondingly loaded on each of the plurality of loading ports LP. Unless otherwise especially stated, one loading port LP will be discussed. However, the disclosures provided herein can apply to each of the plurality of loading ports LP.

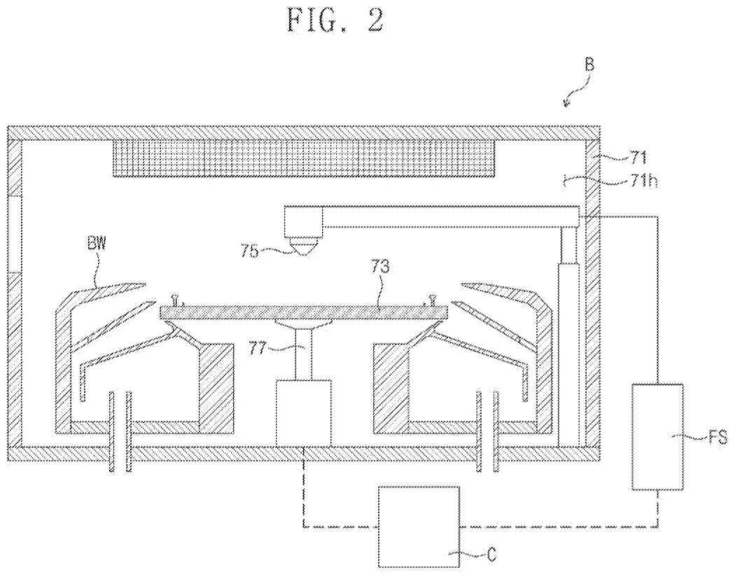

The wet chamber B may be a chamber in which a wet process is performed on a substrate. The wet chamber B may provide a space where a wet process is performed. When a substrate is disposed in the wet chamber B, the substrate may be coated thereon with liquid, such as various chemicals and/or isopropyl alcohol (IPA). The liquid coating may be fulfilled in various ways. For example, a liquid may be sprayed on a substrate that rotates, and a centrifugal force may cause the liquid to uniformly distribute on the substrate. The wet chamber B may be provided in plural. For example, two wet chambers B may be provided. The two wet chambers B may be disposed to face each other. A single wet chamber B, however, will be discussed below. The wet chamber B will be further discussed in detail below with reference to FIG. 2.

The wetting solution supply FS may supply the wet chamber B with fluid. The wetting solution supply FS may comprise a fluid tank, a pump, and so forth. A wetting solution may be defined to indicate a fluid with which the wetting solution supply FS supplies the wet chamber B. The wetting solution may include various chemicals and/or water. For example, the wetting solution may include a developer or isopropyl alcohol (IPA).

The transfer unit TU may transfer a substrate. For example, the transfer unit TU may transfer a substrate loaded on the loading port LP to the wet chamber B. In addition, the transfer unit TU may unload a substrate from the wet chamber B, and may then transfer the unloaded substrate to a dry chamber A which will be discussed below. The transfer unit TU may comprise an actuator such as a motor. A single transfer unit TU may be provided, but the present inventive concepts are not limited thereto.

The substrate processing apparatus D may dry a substrate. The substrate processing apparatus D may include a dry chamber A and a supercritical fluid supply 3.

The dry chamber A may be a chamber to dry a substrate. For example, the dry chamber A may dry and/or clean a substrate that has passed through the wet chamber B. For example, the dry chamber A may remove liquid from a substrate on which the liquid, such as a developer and/or isopropyl alcohol (IPA), is coated in the wet chamber B. The dry chamber A may provide a space where a dry process is performed. The dry chamber A may be provided in plural. For example, two dry chambers A may be provided. The two dry chambers A may be disposed to face each other. A single dry chamber A, however, will be discussed below.

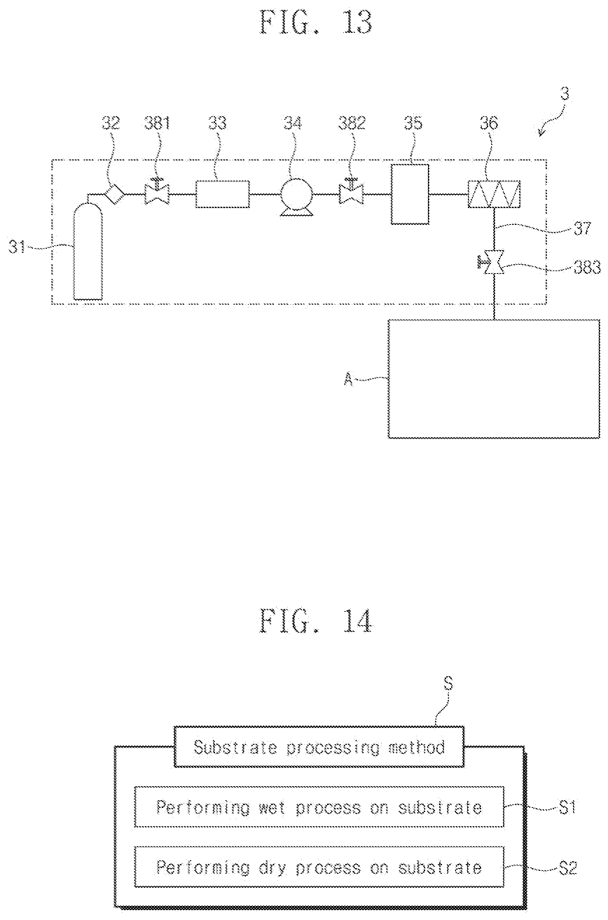

The supercritical fluid supply 3 may supply the dry chamber A with fluid. The supercritical fluid supply 3 may supply a supercritical fluid that is sprayed into the dry chamber A. For example, the supercritical fluid supply 3 may supply the dry chamber A with carbon dioxide (CO₂) in its supercritical fluid (SCF) state. The supercritical fluid supply 3 will be further discussed in detail below with reference to FIG. 13.

The controller C may control the wet chamber B and the dry chamber A. For example, the controller C may control the supercritical fluid supply 3 to adjust the degree of dryness of a substrate. For example, the controller C may change an amount of fluid that is supplied to the dry chamber A.

Although not illustrated, controller C can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller C (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller C can include antennas, network interfaces that provide wireless and/or wire line digital and/or analog interface to one or more networks over one or more network connections (not shown), a power source that provides an appropriate alternating current (AC) or direct current (DC) to power one or more components of the controller C, and a bus that allows communication among the various disclosed components of the controller C.

FIG. 2 illustrates a cross-sectional view showing a cleaning chamber according to some example embodiments of the present inventive concepts.

Referring to FIG. 2, the wet chamber B may include a wet chamber housing 71, a wetting stage 73, a wetting nozzle 75, a rotating shaft 77, and a bowl BW.

The wet chamber housing 71 may provide a wetting space 71h. A wet process may be performed on a substrate disposed in the wetting space 71h.

The wetting stage 73 may be positioned in the wet chamber housing 71. The wetting stage 73 may support a substrate. For example, a substrate inserted into the wet chamber housing 71 may be disposed on the wetting stage 73. The wetting stage 73 may rotate a substrate.

The wetting nozzle 75 may be upwardly spaced apart from the wetting stage 73. For example, the wetting nozzle 75 may be above the wetting stage 73, and may vertically overlap the wetting stage 73. The wetting nozzle 75 may be fluidly connected to the wetting solution supply FS. As used herein, items described as being “fluidly connected” are configured such that a liquid or gas can flow, or be passed, from one item to the other. The wetting nozzle 75 may be supplied with the wetting solution from the wetting solution supply FS, and may spray the wetting solution toward the wetting stage 73.

The controller C may control the rotating shaft 77 to rotate the wetting stage 73. The rotating shaft 77 may rotate the wetting stage 73 in the clockwise direction or the counterclockwise direction. A substrate disposed on the wetting stage 73 may rotate along with the rotation of the wetting stage 73. The rotating shaft 77 may be rotated by a driving device such as a motor.

The bowl BW may surround the wetting stage 73. The bowl BW may collect the wetting solution that is outwardly pushed from the wetting stage 73. For example, wetting solution that is pushed beyond the edges of the wetting stage 73 may be captured and collected by the bowl BW that surrounds the wetting stage 73.

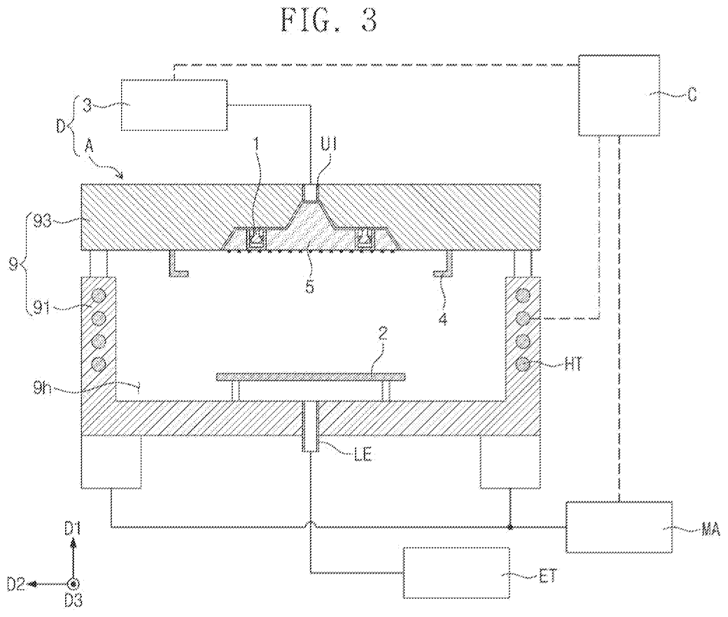

FIG. 3 illustrates a cross-sectional view showing a dry chamber according to some example embodiments of the present inventive concepts.

In the following description, symbol D1 may indicate a first direction D1, symbol D2 may indicate a second direction D2 that intersects the first direction D1, and symbol D3 may indicate a third direction D3 that intersects each of the first and second directions D1 and D2. The first direction D1 may be called a vertical direction. In addition, each of the second and third directions D2 and D3 may be called a horizontal direction.

Referring to FIG. 3, the dry chamber A may dry a substrate. For example, the dry chamber A may remove liquid from a substrate. The dry chamber A may dry a substrate that has been wetted in the wet chamber (see, e.g., wet chamber B of FIG. 2). The dry chamber A may include a dry chamber housing 9, a dry heater HT, a dry chuck 4, a blocking plate 2, a chamber driving mechanism MA, an exhaust tank ET, a substrate processing baffle 5, and a fixing member 1.

The dry chamber housing 9 may provide a drying space 9h. The dry chamber housing 9 may include a lower chamber 91 and an upper chamber 93. The lower chamber 91 may be downwardly spaced apart from the upper chamber 93. For example, the lower chamber 91 may be below the upper chamber 93. The drying space 9h may be provided between the lower chamber 91 and the upper chamber 93. The lower chamber 91 and the upper chamber 93 may enclose the drying space 9h. The lower chamber 91 may be vertically movable. For example, the chamber driving mechanism MA may drive the lower chamber 91 to move upwardly to combine with the upper chamber 93, and the chamber driving mechanism MA may drive the lower chamber 91 to move downwardly to separate from the upper chamber 93. The lower chamber 91 and the upper chamber 93 may be combined to separate the drying space 9h from an external environment.

A fluid inlet UI may be provided to the upper chamber 93. The fluid inlet UI may be fluidly connected to the supercritical fluid supply 3. A supercritical fluid may be supplied from the supercritical fluid supply 3 through the fluid inlet UI to the drying space 9h. A lower outlet LE may be provided to the lower chamber 91. The lower outlet LE may be fluidly connected to the exhaust tank ET. A fluid may be outwardly discharged through the lower outlet LE from the dry chamber housing 9.

The dry heater HT may be coupled to the dry chamber housing 9. The dry heater HT may heat the drying space 9h. The heating of the dry heater HT may permit a supercritical fluid introduced into the drying space 9h to maintain its supercritical state. For example, the dry heater HT may emit heat to the drying space 9h and thereby may maintain a temperature of a supercritical fluid in the drying space 9h at a desired temperature.

The dry chuck 4 may be connected to the upper chamber 93. The dry chuck 4 may be engaged with the upper chamber 93. A substrate may be disposed on the dry chuck 4. For example, the dry chuck 4 may support a substrate. The dry chuck 4 will be further discussed in detail below.

The blocking plate 2 may be connected to the lower chamber 91. The blocking plate 2 may be upwardly spaced apart at a certain interval from the lower outlet LE. For example, the blocking plate 2 may be above the lower outlet LE. The blocking plate 2 may block a flow of fluid. The chamber driving mechanism MA may be associated with the lower chamber 91. The chamber driving mechanism MA may drive the lower chamber 91 to move vertically. The chamber driving mechanism MA may combine the lower chamber 91 with the upper chamber 93, or may separate the lower chamber 91 from the upper chamber 93. The chamber driving mechanism MA may include an actuator such as a motor. The exhaust tank ET may be fluidly connected to the lower outlet LE. The exhaust tank ET may receive a fluid that is discharged through the lower outlet LE.

The substrate processing baffle 5 may be positioned in the dry chamber housing 9. The substrate processing baffle 5 may be coupled to the upper chamber 93. The substrate processing baffle 5 may be positioned, for example, on the dry chuck 4. The dry chuck 4 may be disposed downwardly spaced apart from the substrate processing baffle 5. For example, the dry chuck 4 may be below the substrate processing baffle 5. The substrate processing baffle 5 may be fluidly connected to the supercritical fluid supply 3. For example, the substrate processing baffle 5 may be connected through the fluid inlet UI to the supercritical fluid supply 3. A fluid supplied from the supercritical fluid supply 3 may be introduced to the drying space 9h after passing through the substrate processing baffle 5. The substrate processing baffle 5 will be further discussed in detail below.

The fixing member 1 may connect the substrate processing baffle 5 and the dry chamber housing 9 to each other. The fixing member 1 may be fixedly combined with the upper chamber 93. For example, an upper end of the fixing member 1 may be welded to a bottom surface of the upper chamber 93, thereby being combined with the upper chamber 93. The fixing member 1 will be further discussed in detail below.

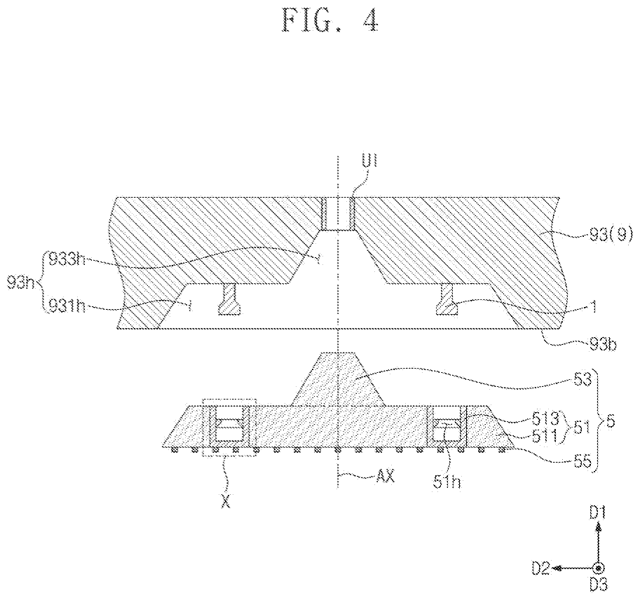

FIG. 4 illustrates an enlarged cross-sectional view partially showing a dry chamber according to some example embodiments of the present inventive concepts.

Referring to FIG. 4, the upper chamber 93 may provide a baffle placement space 93h. The substrate processing baffle 5 may be disposed in the baffle placement space 93h. The baffle placement space 93h may be a space that is upwardly recessed from a bottom surface 93b of the upper chamber 93. The baffle placement space 93h may be fluidly connected to the fluid inlet UI. For example, the fluid inlet UI may extend upwardly from the baffle placement space 93h. The baffle placement space 93h may include a lower space 931h and an upper space 933h. The lower space 931h may be connected to the bottom surface 93b of the upper chamber 93. The upper space 933h may connect the lower space 931h and the fluid inlet UI to each other. The upper space 933h may have a width less than that of the lower space 931h.

The fixing member 1 may be fixedly combined with the upper chamber 93. For example, in the baffle placement space 93h, the fixing member 1 may be rigidly placed on the bottom surface 93b of the upper chamber 93. For example, the fixing member 1 may be welded to the upper chamber 93. As illustrated in FIG. 4, the fixing member 1 may be provided in plurality.

The substrate processing baffle 5 may be coupled through the fixing member 1 to the upper chamber 93. The substrate processing baffle 5 may be disposed in the baffle placement space 93h. The substrate processing baffle 5 may include a plate body 51, an upper body 53, and partition members 55.

The plate body 51 may have a central axis AX. The central axis AX may extend in the first direction D1. The plate body 51 may have a symmetric shape about the central axis AX. The plate body 51 may have a diameter that decreases in an upward direction as shown in FIG. 4, but the present inventive concepts are not limited thereto. The plate body 51 may include a coupling hole 51h. The plate body 51 may be positioned in the lower space 931h in a state where the substrate processing baffle 5 is combined with the upper chamber 93. The plate body 51 may be formed of and/or include metal. For example, the plate body 51 may include one of iron (Fe), chromium (Cr), and nickel (Ni), but the present inventive concepts are not limited thereto. The plate body 51 may include a fine passage member 511 and a coupling member 513. The coupling hole 51h may be defined by the coupling member 513. A detailed description thereof will be further discussed below.

The upper body 53 may be positioned on the plate body 51. The upper body 53 may have an axis aligned with the central axis AX of the plate body 51. The upper body 53 may have a truncated cone shape, but the present inventive concepts are not limited thereto. The upper body 53 may be positioned in the upper space 933h in a state where the substrate processing baffle 5 is combined with the upper chamber 93. The upper body 53 may be formed of and/or include metal. For example, the upper body 53 may include one of iron (Fe), chromium (Cr), and nickel (Ni), but the present inventive concepts are not limited thereto.

The partition member 55 may be combined with the plate body 51. The partition member 55 may be positioned below the coupling hole 51h. For example, the partition member 55 may be coupled to a bottom of the plate body 51. In detail, the partition member 55 may be located on a bottom surface of the plate body 51. The partition member 55 may extend in a horizontal direction. For example, the partition member 55 may extend in the third direction D3. The partition member 55 may be provided in plural. The plurality of partition members 55 may be disposed spaced apart from each other. For example, the plurality of partition members 55 may be disposed spaced apart in the second direction D2 from each other. However, unless otherwise especially stated, a single partition member 55 will be discussed below. The partition members 55 may include metal. For example, the partition members 55 may include one of iron (Fe), chromium (Cr), and nickel (Ni), but the present inventive concepts are not limited thereto. The partition members 55 will be further discussed in detail below.

The plate body 51, the upper body 53, and the partition members 55 may be collectively connected into a single unitary body. For example, a three-dimensional (3D) print process may be employed to form the plate body 51, the upper body 53, and the partition members 55 as a single unitary body. The present inventive concepts, however, are not limited thereto, and the plate body 51, the upper body 53, and the partition members 55 may be independently formed and then combined with each other.

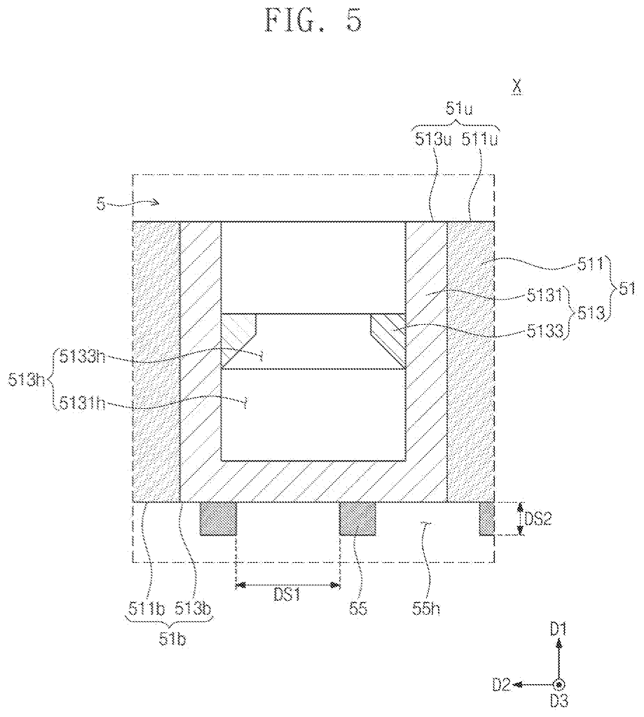

FIG. 5 illustrates an enlarged cross-sectional view showing section X of FIG. 4.

Referring to FIG. 5, the plate body 51 may include a fine passage member 511 and a coupling member 513.

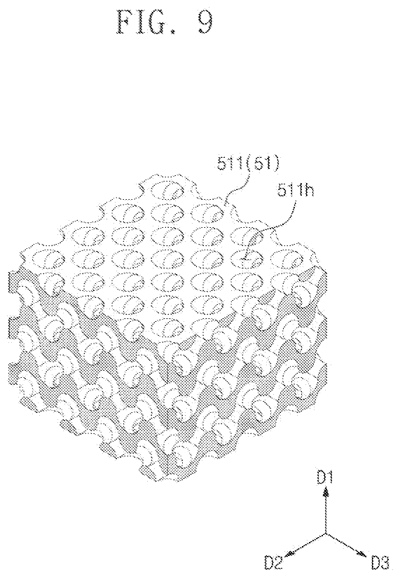

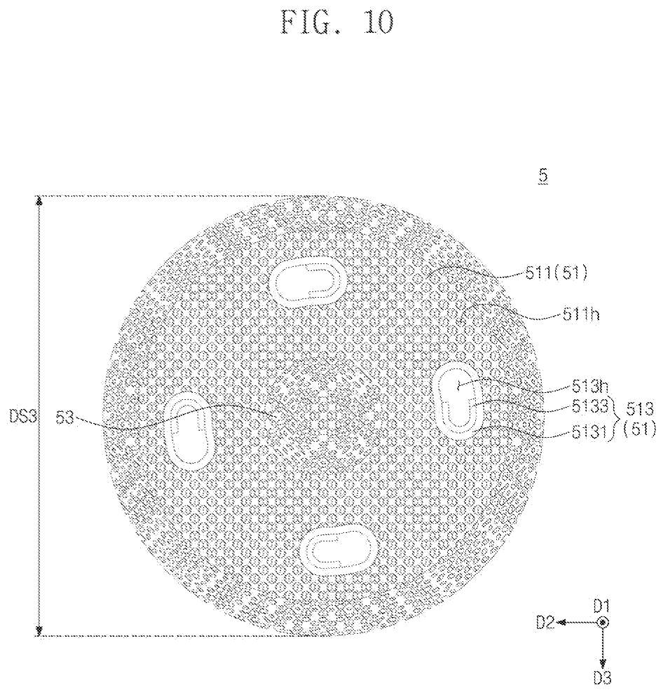

The fine passage member 511 may have a circular shape when viewed in plan as shown in FIGS. 4 and 10. The fine passage member 511 may provide a fine passage (see, e.g., fine passage 511h of FIG. 9). The fine passage member 511 may have a porous structure. The fine passage 511h may indicate a space defined in and by the fine passage member 511. For example, the fine passage member 511 may have a triply periodic minimal surface (TPMS) structure. The fine passage 511h may indicate a space defined in and by the TPMS structured fine passage member 511. The present inventive concepts, however, are not limited thereto, and the fine passage member 511 may have a structure other than the TPMS structure. For example, the fine passage 511h may be defined by the fine passage member 511 having a structure other than the TPMS structure. The fine passage 511h may connect a top surface 51u of the plate body 51 to a bottom surface 51b of the plate body 51. For example, the fine passage 511h may connect a top surface 51u of the plate body 51 to a bottom surface 51b of the plate body 51. A top surface 511u of the fine passage member 511 may be a portion of the top surface 51u of the plate body 51. A bottom surface 511b of the fine passage member 511 may be a portion of the bottom surface 51b of the plate body 51. The fine passage 511h will be further discussed in detail below. The coupling member 513 may provide a coupling hole 513h. The coupling hole 513h may be a space that is downwardly recessed from the top surface 51u of the plate body 51. For example, the coupling hole 513h may indicate a space that is downwardly recessed from a top surface 513u of the coupling member 513. The top surface 513u of the coupling member 513 may be a portion of the top surface 51u of the plate body 51. The top surface 513u of the coupling member 513 may be located at a level substantially the same as or similar to that of the top surface 511u of the fine passage member 511. For example, the top surface 513u of the coupling member 513 and the top surface 511u of the fine passage member 511 may be positioned on the same plane. The present inventive concepts, however, are not limited thereto.

The coupling member 513 may be closed at a lower end thereof. Therefore, the coupling hole 513h may not be connected to the bottom surface 51b of the plate body 51. For example, the coupling hole 513h may not be exposed to a bottom surface 513b of the coupling member 513. The present inventive concepts, however, are not limited thereto, and a fine passage (not shown) may be provided in the coupling member 513. For example, differently from that shown in FIG. 5, the coupling member 513 may also have a TPMS structure. In this case, the coupling hole 513h may be connected to the bottom surface 513b of the coupling member 513 through the TPMS structured fine passage positioned below the coupling hole 513h.

The bottom surface 513b of the coupling member 513 may be a portion of the bottom surface 51b of the plate body 51. The bottom surface 513b of the coupling member 513 may be located at a level substantially the same as or similar to that of the bottom surface 511b of the fine passage member 511. For example, the bottom surface 513b of the coupling member 513 and the bottom surface 511b of the fine passage member 511 may be positioned on the same plane. The present inventive concepts, however, are not limited thereto, and the bottom surface 513b of the coupling member 513 may be located at a higher level than that of the bottom surface 511b of the fine passage member 511. For example, differently from that shown in FIG. 5, the bottom surface 513b of the coupling member 513 may be positioned higher than the bottom surface 511b of the fine passage member 511. Therefore, the bottom surface 513b of the coupling member 513 and the bottom surface 511b of the fine passage member 511 may not be positioned on the same plane.

The coupling member 513 may include a coupling body 5131 and an inner member 5133. A top surface of the coupling body 5131 may be the top surface 513u of the coupling member 513. A bottom surface of the coupling body 5131 may be the bottom surface 513b of the coupling member 513. The coupling body 5131 may define a main coupling hole 5131h. The main coupling hole 5131h may be a portion of the coupling hole 513h. The main coupling hole 5131h may have a constant width, but the present inventive concepts are not limited thereto. The inner member 5133 may be positioned on an inner lateral surface of the coupling body 5131. The inner member 5133 may define a placement hole 5133h. The placement hole 5133h may be a portion of the coupling hole 513h. The placement hole 5133h may have a width that decreases in an upward direction.

A channel 55h may be formed between two neighboring ones among the plurality of partition members 55. A first distance DS1 may indicate a distance between two neighboring ones among the plurality of partition members 55. The first distance DS1 may range, for example, from about 1 mm to about 5 mm. The first distance DS1 may be substantially the same as or similar to a width of the channel 55h. The channels 55h may extend in a horizontal direction. The extending direction of the channels 55h may be substantially the same as that of the partition members 55.

A height of the partition members 55 may be called a second distance DS2. The second distance DS2 may range, for example, from about 0.1 mm to about 4 mm. The height of the partition members 55 may be substantially the same as or similar to a depths of the channels 55h.

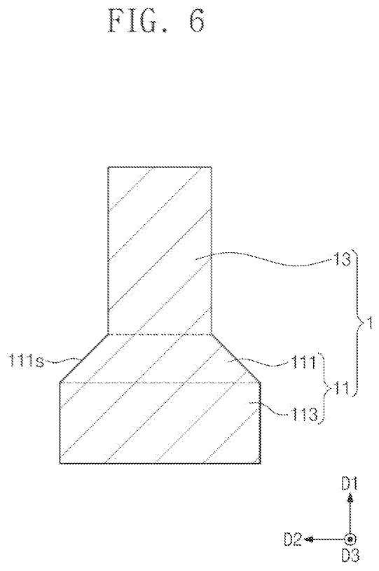

FIG. 6 illustrates a cross-sectional view showing a fixing member according to some example embodiments of the present inventive concepts.

Referring to FIG. 6, the fixing member 1 may include a fixing head 11 and a connection member 13.

The fixing head 11 may include an upper member 111 and a lower member 113. The upper member 111 may have a width that increases in a downward direction. The upper member 111 may have a lateral surface 111s that makes an acute angle with the first direction D1. For example, the lateral surface 111s of the upper member 111 may be inclined.

The upper member 111 may have, for example, a truncated cone shape. The lower member 113 may be positioned below the upper member 111. A width of the lower member 113 may be constant, but the present inventive concepts are not limited thereto.

The connection member 13 may upwardly extend from the fixing head 11. An upper end of the connection member 13 may be fixedly combined with the upper chamber (see, e.g., upper chamber 93 of FIG. 4). A width of the upper member 13 may be constant, but the present inventive concepts are not limited thereto.

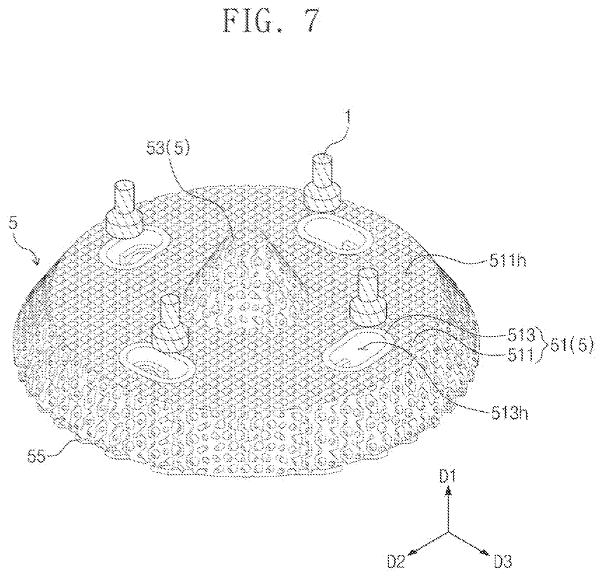

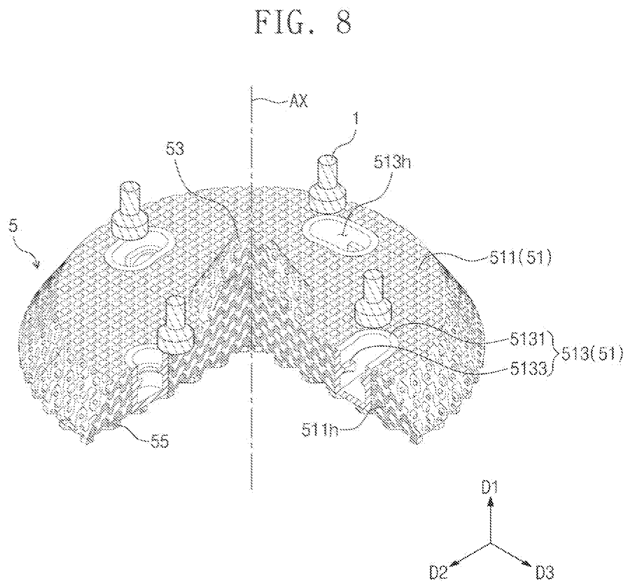

FIG. 7 illustrates a perspective view showing a substrate processing baffle and a coupling member according to some example embodiments of the present inventive concepts. FIG. 8 illustrates a cut-away perspective view showing a substrate processing baffle and a coupling member according to some example embodiments of the present inventive concepts. FIG. 9 illustrates an enlarged perspective view partially showing a substrate processing baffle according to some example embodiments of the present inventive concepts. FIG. 10 illustrates a plan view showing a substrate processing baffle according to some example embodiments of the present inventive concepts.

Referring to FIGS. 7 to 9, the TPMS structure of the fine passage member 511 may be provided. The TPMS structure may define the fine passage 511h. As discussed above, the fine passage 511h may connect the top surface (see, e.g., top surface 51u of FIG. 6) of the plate body 51 to the bottom surface (see, e.g., bottom surface 51b of FIG. 6) of the plate body 51. The fine passage 511h may have a size less than that of the coupling hole 513h. For example, the fine passage 511h may have a planar area less than that of the coupling hole 513h. The fine passage 511h may have a diameter of about 3.0 mm to about 3.5 mm, but the present inventive concepts are not limited thereto.

The fine passage 511h may be provided in plural. The plurality of fine passages 511h may all be connected to each other. The present inventive concepts, however, are not limited thereto, and at least a portion of the plurality of fine passages 511h may not be connected to at least another of the plurality of fine passages 511h.

Referring to FIG. 10, when viewed in plan, the coupling hole 513h may extend a certain distance in a circumferential direction. The coupling member 513 may be provided in plural. For example, as shown in FIG. 10, four coupling members 513 may be provided. The plurality of coupling members 513 may be disposed spaced apart from each other in a circumferential direction. For convenience, the following description will focus on a single coupling member 513.

A diameter of the fine passage member 511 may be called a third distance DS3. The third distance DS3 may be, for example, equal to or greater than about 260 mm. For example, the third distance DS3 may be about 270 mm to about 350 mm. The present inventive concepts, however, are not limited thereto.

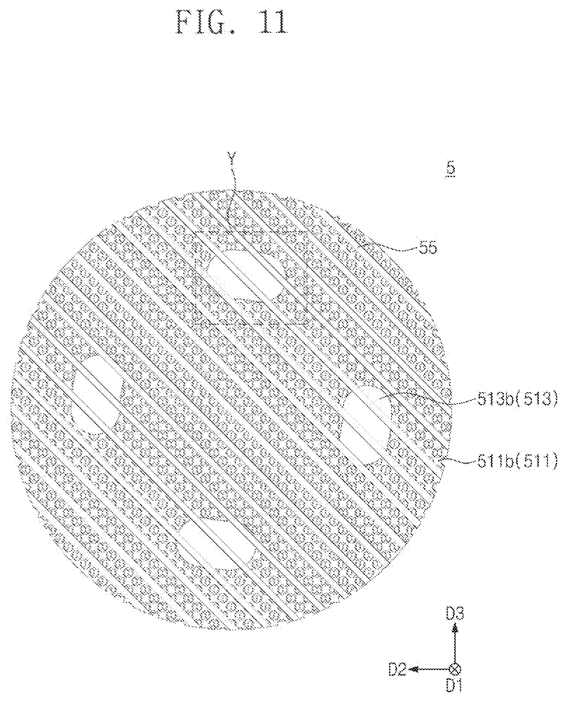

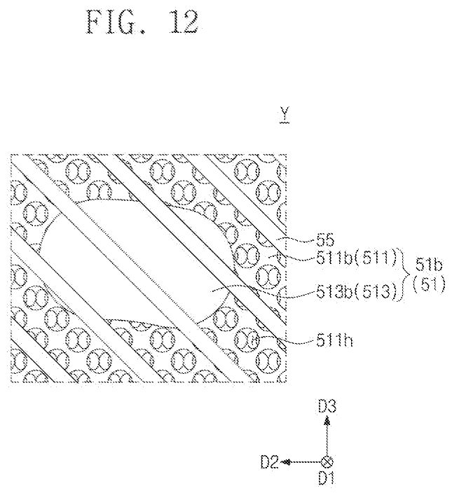

FIG. 11 illustrates a bottom view showing a substrate processing baffle according to some example embodiments of the present inventive concepts. FIG. 12 illustrates an enlarged bottom view showing section Y of FIG. 11.

Referring to FIGS. 11 and 12, the partition members 55 may have a bar shape that extends lengthwise in a horizontal direction. For example, the partition members 55 may not have a curved shape, but may have a straight shape. The plurality of partition members 55 may be parallel to each other. Therefore, the channels (see, e.g., channels 55h of FIG. 5) may have a constant width. The present inventive concepts, however, are not limited thereto, and the channels 55h may have an irregular width. Alternatively, the partition members 55 may have a meandering shape. A detailed description thereof will be further discussed below. For example, the partition members 55 may zig zag in opposite directions, each of which intersects the direction in which the partition members 55 extend.

Referring to FIGS. 5 and 12, the partition members 55 may be associated with the bottom surface 51b of the plate body 51. The partition members 55 may be combined with the bottom surface 513b of the coupling member 513. Thus, the partition members 55 may have a bottom surface (not designated by a reference numeral) located at a lower level than that of the bottom surface 513b of the coupling member 513. For example, the bottom surface of the partition members 55 may be positioned below the bottom surface 513b of the coupling member 513.

FIG. 13 illustrates a simplified schematic diagram showing a supercritical fluid supply according to some example embodiments of the present inventive concepts.

Referring to FIG. 13, the supercritical fluid supply 3 may include a supercritical fluid source 31, a supercritical fluid line 37, a supply filter 32, a first valve 381, a condenser 33, a pump 34, a second valve 382, a tank 35, a heater 36, and a third valve 383.

The supercritical fluid source 31 may supply a supercritical fluid. For example, the supercritical fluid source 31 may store and supply a gaseous fluid which will be a supercritical fluid. When a supercritical fluid is a CO₂ supercritical fluid, the supercritical fluid source 31 may store CO₂ in a gaseous state. The gaseous CO₂ supplied from the supercritical fluid source 31 may have a temperature of about 10° C. to about 30° C. In addition, the gaseous CO₂ supplied from the supercritical fluid source 31 may have a pressure of about 4 MPa to about 6 MPa. A supercritical fluid supplied from the supercritical fluid source 31 may move along the supercritical fluid line 37.

The supercritical fluid line 37 may provide a pathway along which a supercritical fluid is introduced from the supercritical fluid source 31 to the dry chamber A. The supply filter 32 may be positioned on the supercritical fluid line 37. The supply filter 32 may filter foreign substances present in a supercritical fluid. The first valve 381 may control a fluid movement by opening or closing a flow path between the supply filter 32 and the condenser 33.

The condenser 33 may cool gaseous CO₂ supplied from the supercritical fluid source 31. Therefore, the gaseous CO₂ may be liquefied in the condenser 33. For example, the CO₂ liquefied in the condenser 33 may have a temperature of about 0° C. to about 6° C. In addition, the CO₂ liquefied in the condenser 33 may have a pressure of about 4 MPa to about 6 MPa.

The pump 34 may increase a pressure of the supercritical fluid that is liquefied while passing through the condenser 33. For example, the pump 34 may provide a pressure between about 15 MPa and about 25 MPa to the CO₂ liquefied in the condenser 33. In addition, a temperature of CO2 liquefied in the condenser 33 may become about 15° C. to about 25° C. while the CO₂ passes through the pump 34. The second valve 382 may control a fluid movement by opening or closing a pathway between the pump 34 and the tank 35. The tank 35 may store a supercritical fluid that is compressed by the pump 34.

The heater 36 may heat a supercritical fluid that moves along the supercritical fluid line 37. For example, the heater 36 may heat liquid CO₂ that is compressed by the pump 34. Therefore, the liquid CO₂ may become a supercritical state. The CO₂ that becomes a supercritical state by being heated by the heater 36 may be in a state of high temperature and high pressure. For example, the CO₂ that becomes a supercritical state while passing through the heater 36 may have a temperature of about 60°° C. to about 90° C. In addition, the CO₂ that becomes a supercritical state while passing through the heater 36 may have a pressure of about 15 MPa to about 25 MPa. The third valve 383 may control a movement of the CO₂ that becomes a supercritical state while passing through the heater 36. The CO₂ in a supercritical state may be introduced into the dry chamber A after passing through the third valve 383.

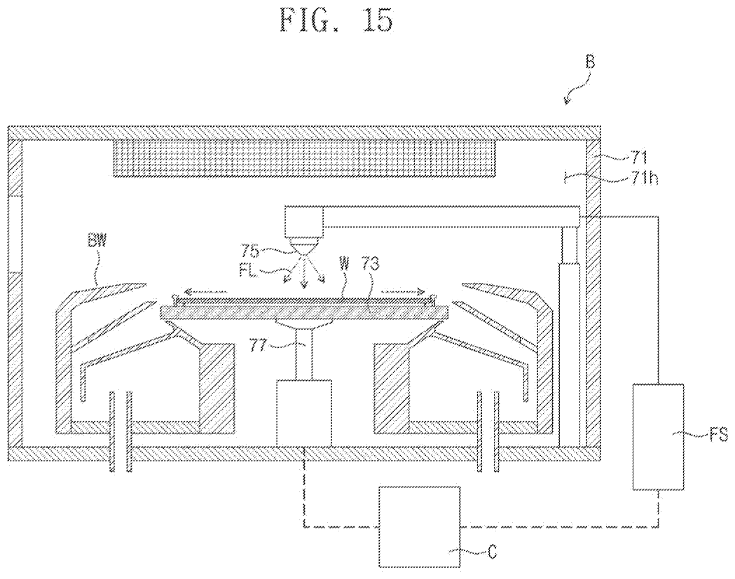

FIG. 14 illustrates a flow chart showing a substrate processing method according to some example embodiments of the present inventive concepts.

Referring to FIG. 14, a substrate processing method S may be provided. The substrate processing method S may be a way of treating a substrate by using the substrate processing system (see, e.g., substrate processing system P of FIG. 1) discussed with reference to FIGS. 1 to 13. The substrate processing method S may include perform a wet process on a substrate (S1) and performing a dry process on the substrate (S2).

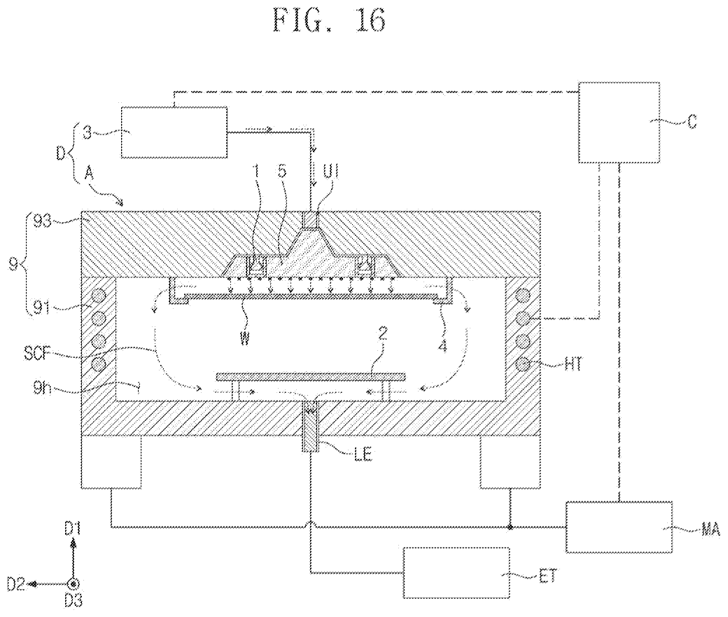

The substrate processing method S will be discussed in detail below with reference to FIGS. 15 and 16.

FIGS. 15 and 16 illustrate diagrams showing an example substrate processing method according to the flow chart of FIG. 14.

Referring to FIGS. 14 and 15, the wet process step S1 may include spraying a wetting solution FL onto a substrate W disposed on the wetting stage 73. For example, the wetting solution FL supplied from the wetting solution supply FS may be sprayed through the wetting nozzle 75 onto the substrate W. In this step, the substrate W may rotate. For example, the rotating shaft 77 may turn to rotate the wetting stage 73, thereby rotating the substrate W. The wetting solution FL sprayed onto the substrate W may be uniformly distributed on the substrate W.

Referring to FIGS. 14 and 16, the dry process step S2 may include supplying the drying space 9h with a supercritical fluid SCF. The supercritical fluid SCF supplied from the supercritical fluid supply 3 may be introduced into the dry chamber housing 9. The supercritical fluid SCF supplied from the supercritical fluid supply 3 may move into the fluid inlet UI. The supercritical fluid SCF may be supplied through the substrate processing baffle 5 to the drying space 9h. For example, the supercritical fluid SCF may be introduced through the fine passages (see, e.g., fine passages 511h of FIG. 7) to the drying space 9h. The supercritical fluid SCF that has passed through the fine passages 511h may be dispersed in a horizontal direction at the channel (see, e.g., channels 55h of FIG. 5) formed between the plurality of partition members (see, e.g., partition members 55 of FIG. 5). Thus, even if the fine passages 511h are not uniformly distributed on the bottom surface 51b of the plate body (see, e.g., plate body 51 of FIG. 5), the supercritical fluid SCF that has passed through the fine passages 511h may be uniformly dispersed. For example, the supercritical fluid SCF that has passed through the fine passages 511h that are irregularly distributed may be uniformly dispersed while moving in a horizontal direction between the channels 55h. The supercritical fluid SCF that has passed through the fine passages 511h may be dispersed while moving in a horizontal direction along the extending direction of the channels 55h. Therefore, the supercritical fluid SCF may be uniformly dispersed on the substrate W. The supercritical fluid SCF supplied to the drying space 9h may remove liquid on the substrate W. For example, a wetting solution FL coated on the substrate W in the wet chamber (see, e.g., wet chamber B of FIG. 2) may be dried by the supercritical fluid SCF in the dry chamber A. For example, a liquid on the substrate W may be pushed away by the supercritical fluid SCF at a high pressure, and thus the substrate W may be dried.

According to a substrate processing baffle, a substrate processing apparatus including the same, and a substrate processing method using the same in accordance with some embodiments of the present inventive concepts, a fine passage having a triply periodic minimal surface (TPMS) structure may be used to disperse a supercritical fluid. The TPMS structured fine passage may not be uniformly formed on a region where is positioned a coupling member for fixing the substrate processing baffle to an upper chamber. Therefore, a plate body may be provided thereunder with a partition member to further horizontally disperse the supercritical fluid that has passed through the fine passage. The supercritical fluid may thus be uniformly dispersed. In this case, the supercritical fluid may be uniformly dispersed even below a coupling member. Accordingly, a substrate may undergo a uniform dry process.

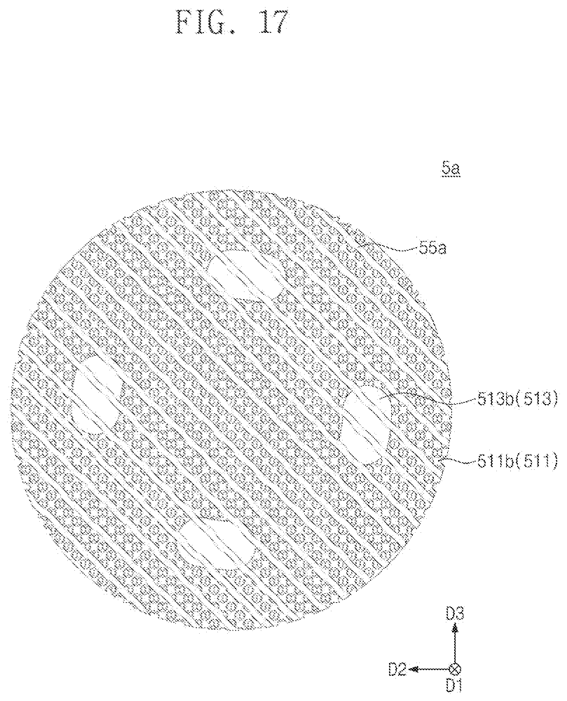

FIG. 17 illustrates a bottom view showing a substrate processing baffle according to some example embodiments of the present inventive concepts.

The following will not repeat descriptions substantially the same as those discussed with reference to FIGS. 1 to 16.

Referring to FIG. 17, a substrate processing baffle 5a may be provided. The substrate processing baffle 5a may include a plate body and partition members 55a. The plate body may include fine passage members 511 and a coupling member 513.

The partition members 55a may extend in a horizontal direction. The partition members 55a may extend meanderingly. The partition members 55a may have a shape that meanderingly extends in a horizontal direction. For example, the partition members 55a may have a wavy shape.

According to a substrate processing baffle, a substrate processing apparatus including the same, and a substrate processing method using the same in accordance with some embodiments of the present inventive concepts, as a partition member has a wavy shape, a supercritical fluid that has passed through a fine passage may experience a large fluid resistance. Therefore, it may be possible to effectively disperse the supercritical fluid that has passed through the fine passage. Accordingly, a dry process may be uniformly performed on a substrate.

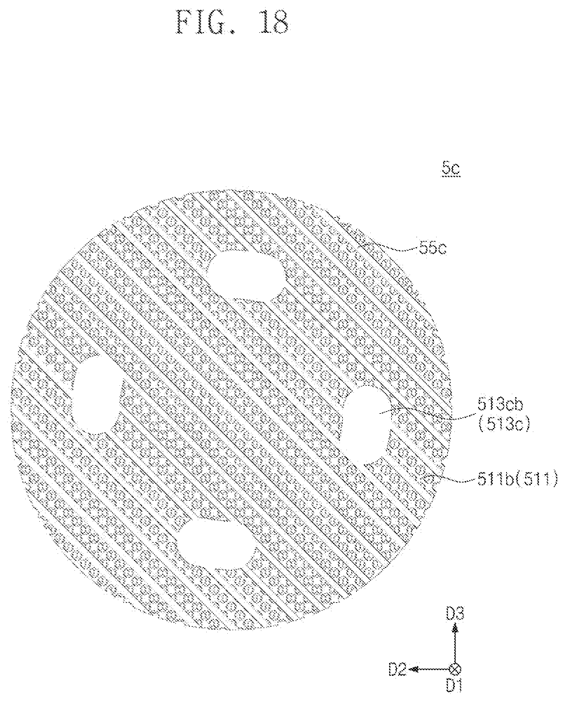

FIG. 18 illustrates a bottom view showing a substrate processing baffle according to some example embodiments of the present inventive concepts.

The following will not repeat descriptions substantially the same as those discussed with reference to FIGS. 1 to 17.

Referring to FIG. 18, a substrate processing baffle 5c may be provided. The substrate processing baffle 5c may include a plate body and partition members 55c. The plate body may include a fine passage member 511 and a coupling member 513c. A bottom surface of each of the partition members 55c may be located at a level substantially the same as or similar to that of a bottom surface 513cb of each of the coupling members 513c. For example, the bottom surfaces of the partition members 55c and the bottom surfaces 513cb of the coupling members 513c may be positioned on the same plane.

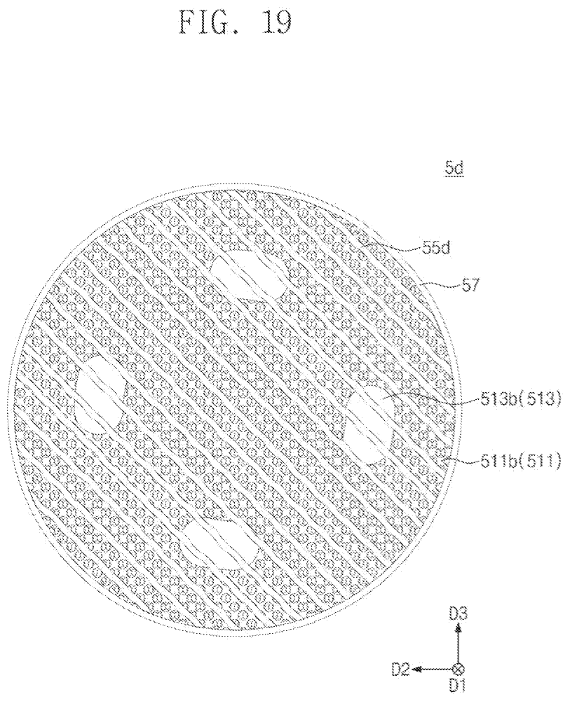

FIG. 19 illustrates a bottom view showing a substrate processing baffle according to some example embodiments of the present inventive concept.

The following will omit a description substantially the same as or similar to that discussed with reference to FIGS. 1 to 18.

Referring to FIG. 19, a substrate processing baffle 5d may be provided. The substrate processing baffle 5d may include a plate body, partition members 55d, and a support member 57.

The support member 57 may have a ring shape. The support member 57 may be combined with an edge of a bottom surface of the plate body. For example, the support member 57 may be coupled to an edge of the fine passage member 511. The partition members 55d may be connected to the support member 57. For example, opposite ends of each of the partition members 55d may contact and be connected to the support member 57.

According to a substrate processing baffle of the present inventive concepts, a substrate processing apparatus including the same, and a substrate processing method using the same, a supercritical fluid may be uniformly dispersed.

According to a substrate processing baffle of the present inventive concepts, a substrate processing apparatus including the same, and a substrate processing method using the same, a flow of supercritical fluid may be controlled at a position below a coupling hole.

According to a substrate processing baffle of the present inventive concepts, a substrate processing apparatus including the same, and a substrate processing method using the same, a substrate may be easily cleaned.

Effects of the present inventive concepts are not limited to the mentioned above, other effects which have not been mentioned above will be clearly understood to those skilled in the art from the following description.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

1. A substrate processing baffle, comprising:
a plate body that has a central axis extending in a first direction;
an upper body on the plate body; and
a plurality of partition members that extend in a second direction intersecting the first direction, the second direction being a horizontal direction,
wherein the plate body includes:
a fine passage that connects a top surface of the plate body to a bottom surface of the plate body; and
a coupling hole downwardly recessed from the top surface of the plate body,
wherein the plurality of partition members are spaced apart from each other in a third direction that intersects each of the first direction and the second direction, and
wherein the plurality of partition members are lower than the coupling hole.

2. The substrate processing baffle of claim 1, wherein the plurality of partition members are on the bottom surface of the plate body.

3. The substrate processing baffle of claim 1,
wherein the plate body includes:
a fine passage member that has a triply periodic minimal surface (TPMS) structure defining the fine passage; and
a coupling member that defines the coupling hole,
wherein the fine passage member has a circular shape when viewed in plan, and
wherein the coupling member is in the fine passage member.

4. The substrate processing baffle of claim 3,
wherein the coupling member is a plurality of coupling members, and
wherein the plurality of coupling members are spaced apart from each other in a circumferential direction.

5. The substrate processing baffle of claim 3,
wherein a lower end of the coupling member is closed, and
wherein the coupling hole is not connected to the bottom surface of the plate body.

6. The substrate processing baffle of claim 3, wherein the plurality of partition members are combined with a bottom surface of the coupling member.

7. The substrate processing baffle of claim 1, wherein the bottom surface of the plate body and a bottom surface of each of the plurality of partition members are on the same plane.

8. The substrate processing baffle of claim 1,
wherein each of the plurality of partition members has a bar shape that extends lengthwise in the second direction, and
wherein the plurality of partition members are parallel to each other.

9. The substrate processing baffle of claim 1, wherein each of the plurality of partition members has a shape that meanderingly extends in the second direction.

10. The substrate processing baffle of claim 1, further comprising:
a ring-shaped support member combined with an edge of the bottom surface of the plate body,
wherein each of the plurality of partition members is connected to the ring-shaped support member.

11. A substrate processing apparatus, comprising:
a dry chamber housing that provides a drying space; and
a substrate processing baffle in the dry chamber housing,
wherein the substrate processing baffle includes:
a plate body; and
a plurality of partition members combined with the plate body, the plurality of partition members extending in a horizontal direction,
wherein the plate body includes:
a fine passage exposed on a bottom surface of the plate body; and
a coupling hole exposed on a top surface of the plate body, and
wherein the plurality of partition members are below the coupling hole and spaced apart from each other.

12. The substrate processing apparatus of claim 11, further comprising:
a fixing member that connects the dry chamber housing to the substrate processing baffle,
wherein one end of the fixing member is connected to the dry chamber housing, and
wherein another end of the fixing member is inserted into the coupling hole.

13. The substrate processing apparatus of claim 11,
wherein a depth of the coupling hole is less than a thickness of the plate body, and
wherein the coupling hole is not connected to the bottom surface of the plate body.

14. The substrate processing apparatus of claim 11, further comprising a dry chuck in the dry chamber housing and downwardly spaced apart from the substrate processing baffle.

15. The substrate processing apparatus of claim 11,
wherein the plate body includes:
a fine passage member that has a triply periodic minimal surface (TPMS) structure defining the fine passage; and
a coupling member that defines the coupling hole,
wherein the fine passage member has a circular shape when viewed in plan,
wherein the coupling member is a plurality of coupling members, and
wherein the plurality of coupling members are spaced apart from each other in a circumferential direction.

16. The substrate processing apparatus of claim 11, further comprising a supercritical fluid supply that supplies the drying space with a supercritical fluid.

17. A substrate processing baffle, comprising:
a plate body; and
a plurality of partition members that extend in a horizontal direction,
wherein the plate body includes:
a fine passage member that has a triply periodic minimal surface (TPMS) structure defining a fine passage; and
a plurality of coupling members that provide a coupling hole,
wherein the fine passage member has a circular shape when viewed in plan,
wherein the plurality of coupling members are spaced apart from each other in a circumferential direction in the fine passage member,
wherein the fine passage connects a top surface of the fine passage member to a bottom surface of the fine passage member,
wherein the coupling hole is exposed on a top surface of the coupling member,
wherein the plurality of partition members are below the coupling hole, and
wherein the plurality of partition members are spaced apart from each other to form a channel between the plurality of partition members.

18. The substrate processing baffle of claim 17, wherein the plate body includes one of iron (Fe), chromium (Cr), and nickel (Ni).

19. The substrate processing baffle of claim 17, wherein a distance between two neighboring ones among the plurality of partition members is in a range of about 1 mm to about 5 mm.

20. The substrate processing baffle of claim 17, wherein the fine passage member, the plurality of coupling members, and the plurality of partition members are formed into a single unitary body.

21.-25. (canceled)
